(19) United States
(12) Patent Application Publication
(10) Pub. No.: US 2005/0001292 A1
(43) Pub. Date: Jan. 6, 2005

(54) Semiconductor device and lead frame

(75) Inventor: Kazushi Hatauchi, Hyogo (JP)

Correspondence Address: McDermott, Will & Emery, 600 13th Street, N.W., Washington, DC, 20005-3096, US

(73) Assignee: Renesas Technology Corp.

(21) Appl. No.: 10/881,470

(22) Filed: Jul. 1, 2004

(30) Foreign Application Priority Data
Jul. 2, 2003 (JP) 2003-190465

(51) Int. Cl. H01L 23/495

(52) U.S. Cl. 257/666

(57) ABSTRACT

A QFN package includes a semiconductor chip, a die pad including a main surface carrying the semiconductor chip, a plurality of external leads arranged along a periphery of the die pad, spaced from each other and electrically connected to the semiconductor chip, and a mold resin including a side surface. The external lead has one end opposed to the semiconductor chip and the other end not covered with the mold resin and extending on the same plane as the side surface. The other end of the external lead is smaller in size in a direction of alignment of the plurality of external leads than the one end. These structures provide a semiconductor device and a lead frame, which reliably prevent short circuit between lead terminals, and allow smooth cutting with a rotary blade.

### BACKGROUND OF THE INVENTION

1. Field of the Invention

The present invention generally relates to a semiconductor device and a lead frame used for manufacturing the semiconductor device, and particularly to a semiconductor device of a collective mold type and a lead frame used for manufacturing the same.

2. Description of the Background Art

In certain types of known methods of manufacturing semiconductor packages, molding is collectively effected on a region of a lead frame, in which a plurality of semiconductor chips are arranged in a matrix form, and the lead frame is cut along predetermined cut lines to separate the plurality of semiconductor packages from each other.

In contrast to the method, in which each region corresponding to one semiconductor package is molded independently of the other regions, it is necessary in the above method to cut the lead frame together with a resin member formed by the molding. Therefore, a circular disk-like blade is used for such cutting instead of dies for press working, and the cutting is performed by rotating and moving the blade along the cut lines on the lead frame.

Japanese Patent Laying-Open No. 2002-261193 has disclosed a method of manufacturing a semiconductor device, which is aimed at improving packaging properties of a QFN (Quad Flat Non-leaded) package.

The method of manufacturing the semiconductor device disclosed in the Japanese Patent Laying-Open No. 2002-261193 uses a lead frame provided with concave portions having a small thickness. The concave portions are located at portions of the lead frame to be cut by a blade, and are formed on the opposite surfaces of the lead frame. The provision of such concave portions can prevent formation of burrs, which may be left by cutting, and may project from a connection surface of a lead of the QFN package (i.e., a surface opposed to a mounting surface of an interconnection board when the QFN package is mounted on the interconnection board). Thereby, the connection surface of the lead can have an improved flatness, and the QFN package can have improved packaging properties.

Another Japanese Patent Laying-Open No. 06-224342 has disclosed a lead frame and a method of manufacturing the same, which are aimed at improvement in alignment accuracy of an end of an inner lead and a pad. Further, Japanese Patent Laying-Open No. 2001-244399 has disclosed a lead frame and a method of manufacturing a resin-sealed semiconductor device, which are aimed at improvement in cut quality and productivity of a single-side sealed semiconductor package. Further, Japanese Patent Laying-Open No. 01-133340 has disclosed a lead frame and a method of manufacturing the same, which are aimed at preventing a short circuit between neighboring leads and improving reliability.

A disk-like blade is used for cutting the above lead frame, which is molded collectively. Such cutting leaves burrs extending in a traveling direction of the blade on a cut surface of the lead frame. In particular, if the lead frame is made of a relatively soft material such as copper, large burrs are left. These burrs may cause a short-circuit between lead terminals neighboring in the traveling direction of the blade. A similar problem also arises in the case, where the lead frame disclosed in Japanese Patent Laying-Open No. 2002-261193 already described by a disk-like blade.

If the disk-like blade is used for cutting the lead frame, a cutting edge of the blade wears to a larger extent with usage in the cut operations. This requires frequent replacement of the blades. The blade having the cutting edge of diamond is every expensive, and this results in a high production cost of the semiconductor packages.

### SUMMARY OF THE INVENTION

An object of the invention is to overcome the above problem, and particularly to provide a semiconductor device and a lead frame, which can reliably prevent a short-circuit between lead terminals, and allows smooth cutting by a rotary blade.

A semiconductor device according to the invention includes a semiconductor chip; a die pad including a main surface carrying the semiconductor chip; a plurality of lead terminals arranged along a periphery of the die pad, spaced from each other and electrically connected to the semiconductor chip; and a resin member covering the semiconductor chip, the die pad and partially the lead terminals, and including a side surface. Each of the lead terminals has one end opposed to the semiconductor chip and the other end uncovered with the resin member and extending on the same plane as the side surface. The other end is smaller in size in a direction of alignment of the plurality of lead terminals than the one end.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing a QFN package according to a first embodiment of the invention.

FIG. 2 is a bottom view of the QFN package viewed in a direction of an arrow II in FIG. 1.

FIG. 3 is a perspective view showing a first step in a method of manufacturing the QFN package shown in FIG. 1.

FIG. 4 is a plan showing a rear side of a region surrounded by alternate long and two short dashes line in FIG. 3.

FIGS. 5 and 6 are cross sections showing 2nd and 3rd steps in the method of manufacturing the QFN package shown in FIG. 1, respectively.

FIG. 7 is a perspective view showing a 4th step in the method of manufacturing the QFN package shown in FIG. 1.

FIG. 8 is a cross section taken along line VIII-VIII in FIG. 7.

FIG. 9 is a perspective view showing a 5th step in the method of manufacturing the QFN package shown in FIG. 1.

FIG. 10 is a side view of the QFN package viewed in a direction of an arrow X in FIG. 1.

FIG. 11 is a cross section showing a step of mounting the QFN package shown in FIG. 1 on an interconnection board.

FIG. 12 is a perspective view showing a QFN package according to a second embodiment of the invention.

FIG. 13 is a plan showing a lead frame used in steps of manufacturing the QFN package according to a third embodiment of the invention.

FIG. 14 is a bottom view showing a QFN package according to a fourth embodiment of the invention.

FIG. 15 is a plan showing a lead frame used in steps of manufacturing the QFN package in FIG. 14.

FIG. 16 is a bottom view showing a QFN package according to a fifth embodiment of the invention.

FIG. 17 is a plan showing a lead frame used in steps of manufacturing the QFN package shown in FIG. 16.

FIG. 18 is a bottom view of a QFN package according to a sixth embodiment of the invention.

FIG. 19 is a bottom view of a QFN package according to a seventh embodiment of the invention.

FIG. 20 is a plan showing a lead frame according to an eighth embodiment of the invention.

### DESCRIPTION OF THE PREFERRED EMBODIMENTS

Embodiments of the invention will now be described with reference to the drawings.

### First Embodiment

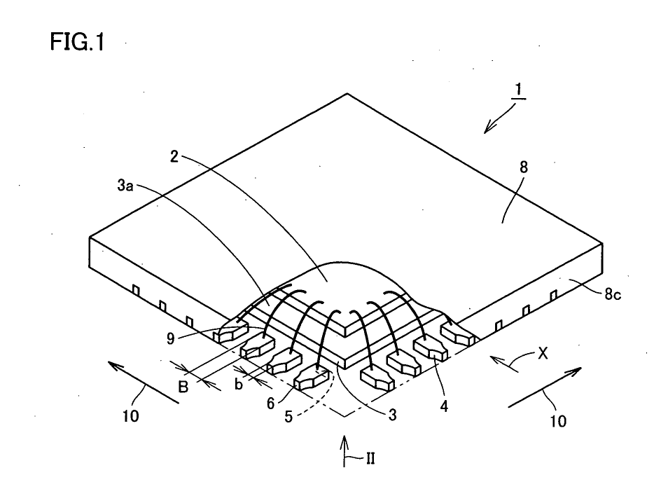

FIG. 1 shows a QFN (Quad Flat Non-leaded) package with a certain part cut away for illustrating an internal structure. The QFN package is a semiconductor package, in which lead terminals are arranged on four sides surrounding a semiconductor chip. The lead terminals are exposed on a bottom side of the package, which has a flat bottom surface.

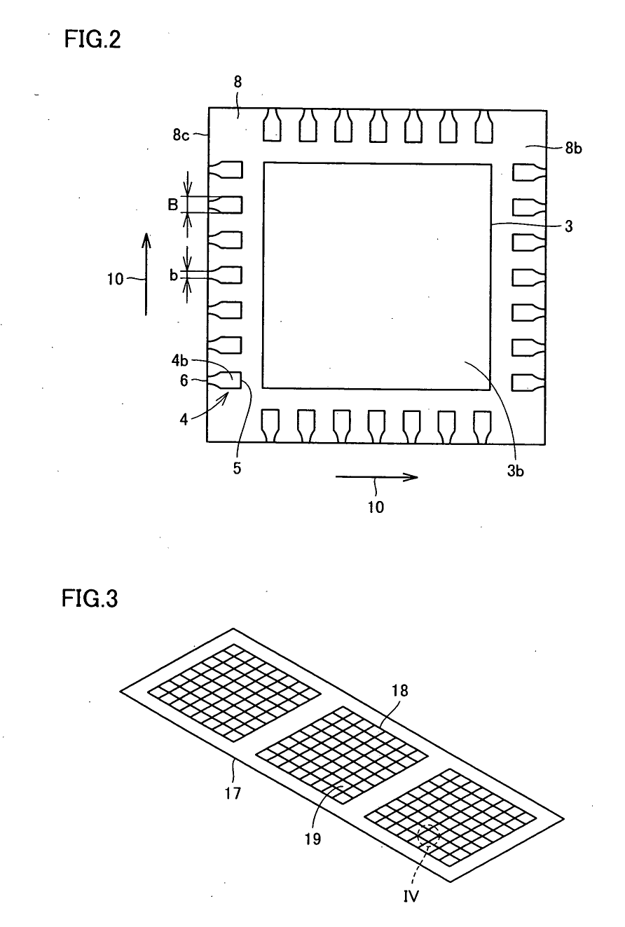

Referring to FIGS. 1 and 2, a QFN package 1 includes a die pad 3 having a main surface 3 a, a semiconductor chip 2 positioned on main surface 3 a, a plurality of external leads 4 arranged along a periphery of die pad 3, bonding wires 9 extending from terminals of semiconductor chip 2 to external leads 4, respectively, and a mold resin 8 covering the foregoing parts and portions.

Mold resin 8 has a rectangular parallelepiped form, and has side surfaces 8c directed in four directions, respectively, and a rear surface 8b opposed to an interconnection board, on which QFN package 1 is mounted. Mold resin 8 is made of, e.g., epoxy resin or silicon resin containing additives such as a curing agent or filler, if necessary.

Die pad 3 has a rectangular plate-like form, and has a rear surface 3b opposite to main surface 3a. Semiconductor chip 2 is fixed to a central region of main surface 3a by an adhesive (not shown). Semiconductor chip 2 is, e.g., a CPU (Central Processing Unit). Mold resin 8 covers semiconductor chip 2, a portion of main surface 3 a not covered with semiconductor chip 2, and the side surfaces of die pad 3 continuing to main surface 3a and rear surface 3b.

Rear surface 3b of die pad 3 is not covered with mold resin 8, and extends on the same plane as rear surface 8b of mold resin 8. By forming mold resin 8 without covering rear surface 3b of die pad 3, a heat generated from semiconductor chip 2 can efficiently escape from the rear side including rear surface 3b.

In a position spaced by a predetermined distance from the periphery of die pad 3, there are arranged external leads 4 each extending away from die pad 3. Each external lead 4 is made of, e.g., copper.

Each external lead 4 has one end 5 opposed to semiconductor chip 2 on main surface 3a and the other end 6 remote from one end 5, and also has a connection surface 4b extending from one end 5 to the other end 6. One end 5 is covered with mold resin 8. The other end 6 extends on the same plane as side surface 8c of mold resin 8. Connection surface 4b is an terminal surface, which is connected to a circuit of an interconnection board via solder when QFN package 1 is mounted on the interconnection board. Connection surface 4b extends on the same plane as rear surface 8b of mold resin 8.

The plurality of external leads 4 are aligned along the periphery of die pad 3, and are spaced from each other in a direction indicated by an arrow 10. Thus, external leads 4 are arranged in the positions surrounding the periphery of semiconductor chip 2, and are spaced from each other by a predetermined distance. In the direction indicated by arrow 10, sizes of each external lead 4, which will be referred to as widths of external lead 4, hereinafter, are determined such that one end 5 has a width B, and the other end 6 has a width b smaller than width B. Thus, external lead 4 has a portion converging in width toward the other end 6. A size of external lead 4 perpendicular to connection surface 4b, which will be referred to as a thickness of external lead 4, is constant throughout a region between opposite ends 5 and 6.

QFN package 1, which is the semiconductor device according to the first embodiment of the invention, includes semiconductor chip 2, die pad 3 including a surface 3a carrying semiconductor chip 2, external leads 4, which are arranged along the periphery of die pad 3 with a spaced between each other, and serve as the plurality of lead terminals electrically connected to semiconductor chip 2, respectively, and mold resin 8 serving as a resin member covering semiconductor chip 2, die pad 3 and a portion of each of external leads 4, and including side surfaces 8c.

External leads 4 has one end 5 opposed to semiconductor chip 2, and the other end 6 not covered with mold resin 8 and extending on the same plane as side surface 8c. The size of each external lead 4 in the direction of alignment of the plurality of external leads 4 indicated by arrow 10 is determined such that the length of the other end 6 is shorter than the length of one end 5.

Die pad 3 further includes rear surface 3b, which is opposite to main surface 3a, and serves as a first surface not covered with mold resin 8. External lead 4 further includes connection surface 4b, which extends from one end 5 to the other end 6 on the substantially same plane as rear surface 3b, and serves as a second surface not covered with mold resin 8.

In this embodiment, the semiconductor device according to the invention is applied to QFN package 1, but naturally, this is not restrictive. Instead of QFN package 1, the semiconductor device according to invention may be applied, e.g., to an SON (Single Outline Non-leaded) package, in which external leads are arranged on two opposite sides of the semiconductor chip.

External lead 4 may have a form, of which width gradually decreases as the position moves from one end 5 toward the other end 6. Also, external lead 4 may have a form having a stepped portion in a position intermediate between ends 5 and 6.

Referring to FIG. 1 and FIGS. 3 to 11, a method of manufacturing QFN package 1 in FIG. 1 will now be described.

Referring to FIG. 3, press working or etching is effected on a copper plate to provide a patterned copper plate of a predetermined configuration. Thereby, a lead frame 17 is formed. Lead frame 1-7 is provided with a plurality of semiconductor package formation regions 18 spaced from each other. In semiconductor package formation region 18, units 19 are formed in a matrix form. Units 19 form regions, which will be divided into independent semiconductor packages in latter steps, respectively.

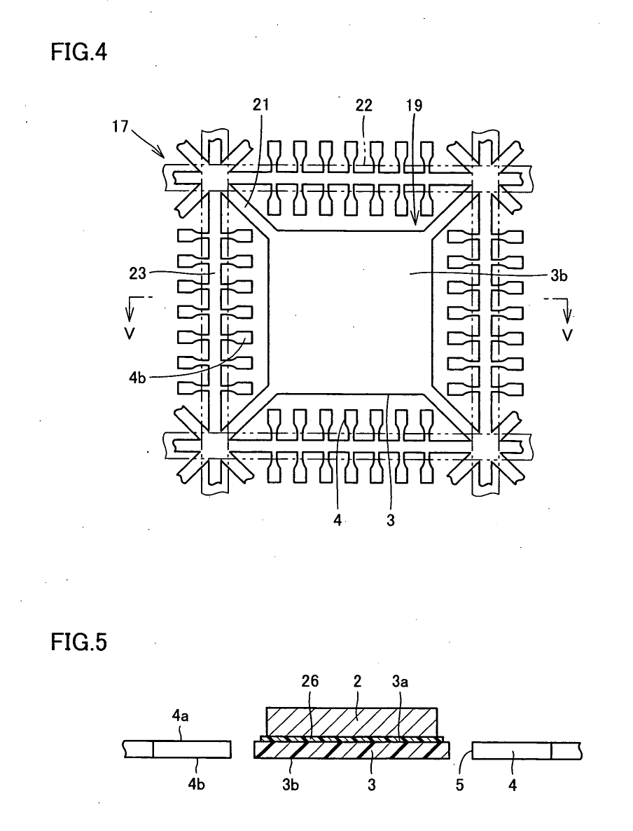

Referring to FIG. 4, unit 19 is formed in a region surrounded by four die bars 23. Unit 19 is formed of die pad 3, suspending leads 21 coupling die pad 3 to die bars 23, and the plurality of external leads 4 extending from die bars 23 toward die pad 3. External lead 4 has a portion, which continues to die bar 23 and has a smaller width than a width of a portion opposed to die pad 3.

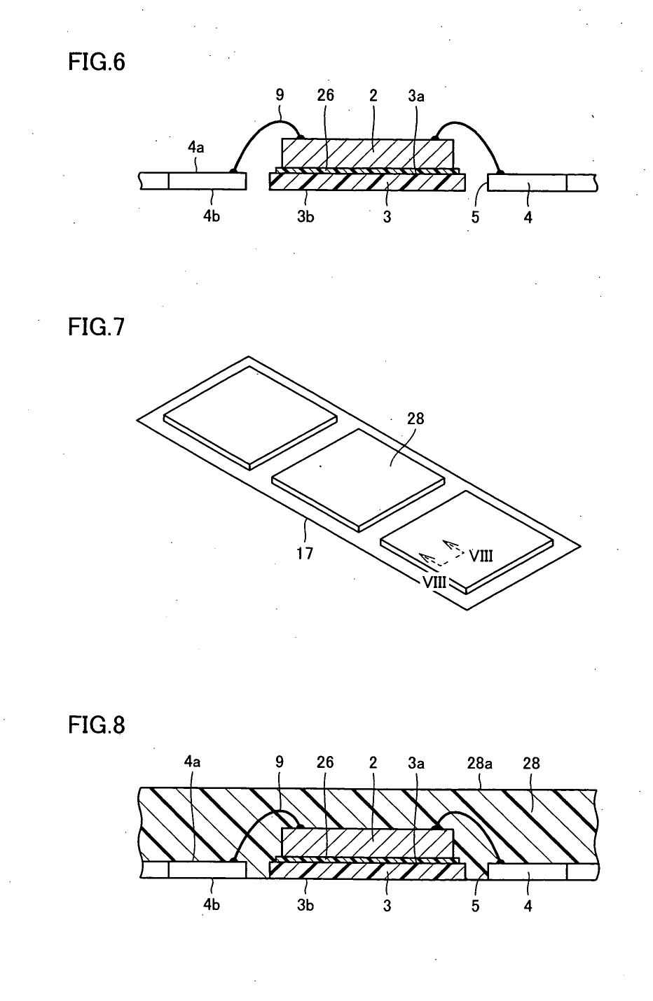

Cross sections of FIG. 5 and FIGS. 6, 8 and 11 are taken along line V-V in FIG. 4. Referring to FIG. 5, an adhesive 26 is applied to a rear surface of semiconductor chip 2. Adhesive 26 may be paste adhesive or film-like adhesive. Thereby, semiconductor chip 2 is adhered to main surface 3a of die pad 3.

Referring to FIG. 6, supersonic thermo-compression bonding or the like is executed to connect the terminals of semiconductor chip 2 to top surfaces 4a of external leads 4 via bonding wires 9, respectively. Bonding wires 9 may be formed of, e.g., gold (Au) wire.

Referring to FIGS. 7 and 8, a mold resin 28 is applied over the surface of lead frame 17 to cover completely semiconductor chips 2 and bonding wires 9. In this processing, such a manner is not employed that mold resin 28 covers each unit 19 in FIG. 3 independently of the others, but mold resin 28 is collectively applied over whole semiconductor package formation regions 18.

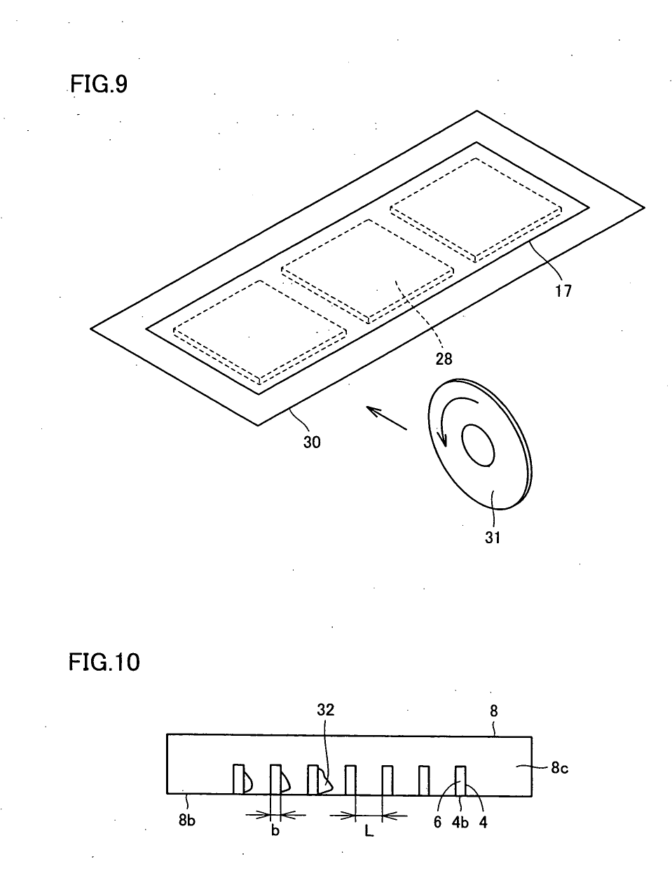

Referring to FIG. 9, a dicing sheet 30 is adhered onto a top surface of mold resin 28, and then the whole structure is turned over to locate lead frame 17 on the top side. A rotating rotary blade 31 is moved along a cut line 22 in FIG. 4 to cut lead frame 17 into units 19 shown in FIG. 3. The blade edge of rotary blade 31 has a width corresponding to a width of cut line 22, and is, for example, equal to about 0.3 mm.

In this cutting step, lead frame 17 is cut to from the plurality of QFN packages 1 shown in FIG. 1. Since lead frame 17 and mold resin 28 are simultaneously cut, the other ends 6 of external leads 4 extend on the same plane as side surface 8c of mold resin 8.

Referring to FIG. 10, since rotary blade 31 cuts lead frame 17, the other end 6 of external lead 4 is defined by a cut surface. Therefore, a burr 32 projecting in the traveling direction of rotary blade 31 is left on the other end 6 of external lead 4.

In QFN package 1, the other end 6 of external lead 4 has width b smaller than width B of one end 5. Therefore, a large distance L can be kept between neighboring external leads 4 while maintaining an appropriate pitch of arrangement of external leads 4. Since the other end 6 has a smaller width than one end 5, it is possible to reduce a resistance, which occurs between external lead 4 and rotary blade 31 during the cutting operation. This can reduce sizes of burrs 32. For the above reasons, such a situation can be prevented that burr 32 formed on the other end 6 of external lead 4 is in contact with neighboring external lead 4.

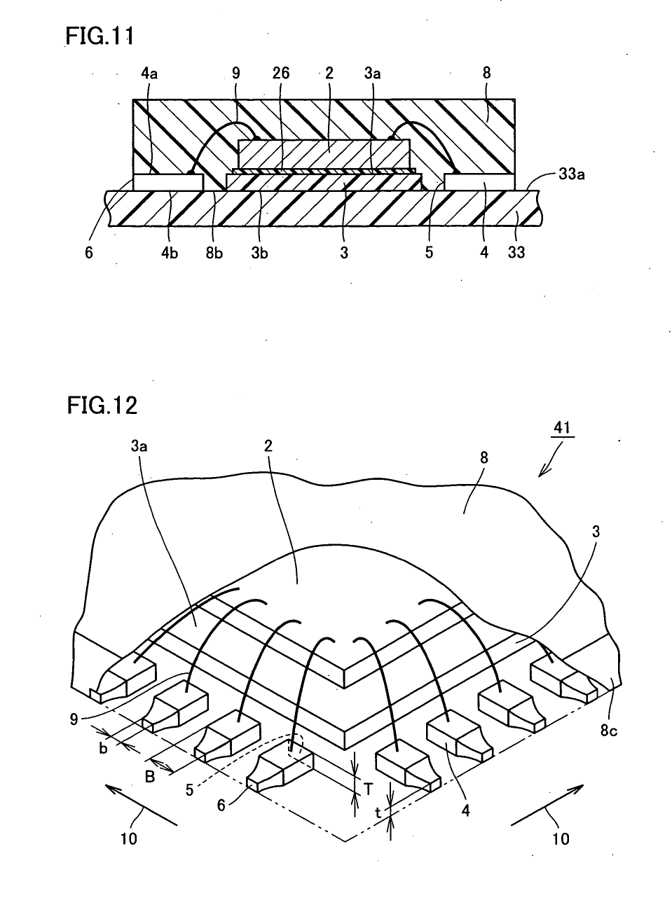

Referring to FIG. 11, an interconnection board 33, which is provided at its surface 33a with a predetermined circuit, is prepared. QFN package 1 is positioned on surface 33a of interconnection board 33 such that surface 33a is opposed to rear surface 8b of mold resin 8. The circuit formed on surface 33 a is connected to connection surface 4b of each external lead 4 by soldering so that QFN package 1 is mounted on interconnection board 33. In this processing, surface 33a may be joined to rear surface 3b of die pad 3 by soldering. Thereby, a heat generated from semiconductor chip 2 can escape through the solder to interconnection board 33.

According to the method of manufacturing QFN package 1, as described above, mold resin 28 collectively covers the regions to be cut to provide the plurality of QFN packages 1. This method achieves such an advantage that an attachment margin between the packages is not required in lead frame 17. Further, QFN package 1 can have reduced sizes because external leads 4 do not protrude from the side surfaces of mold resin 8.

Further, mold resin 28, which is collectively formed, has a form independent of the form of each package. Therefore, it is not necessary to prepare new dies for the mold resins when packages of new design or specifications are to be formed. This can reduce a cost and a period required for developing new packages.

QFN package 1 having the above structure can avoid such a situation that burr 32 formed on the other end 6 of external lead 4 short-circuits neighboring external leads 4. Thereby, it is possible to achieve the semiconductor package, which exhibits intended electric characteristics and has high reliability. Since it is possible to reduce the resistance between external lead 4 and rotary blade 31 in the cutting operation, wearing of rotary blade 31 can be reduced. Thereby, the step of cutting the semiconductor package can be smoothly executed, and the production cost of the semiconductor packages can be reduced.

The situation, in which the burrs are left in the operation of cutting the lead frame, may occur not only in the case employing the collective molding but also in the case where each semiconductor package is covered with an independent mold resin. In the latter case, however, dies for ordinary press working is used for cutting the lead frame so that the burrs formed thereby project toward a mount surface of the semiconductor package. Therefore, the effect of the invention, i.e., prevention of the short circuit between the neighboring external leads can be achieved particularly in the semiconductor package prepared by the collective molding.

In the semiconductor package formed by the collective molding, the side surface of the mold resin and the cut surface of the external lead are formed on the same plane. Therefore, the burr on the external lead is likely formed in the state, where it is buried in the mold resin. If the burr is formed in this state, it is very difficult to remove the burr in a later stage. Accordingly, the invention can be useful and advantageous because the invention can prevent formation of large burrs, and can suppress short circuit even if the burr is formed.

### Second Embodiment

A QFN package according to the second embodiment of the invention has a structure basically similar to QFN package 1 according to the first embodiment. In the following description, description of the same structures is not repeated.

FIG. 12 shows the QFN package with a certain part cut away for illustrating an internal structure.

Referring to FIG. 12, a QFN package 41 has external leads 4 each having one end 5, which has width B larger than width b of the other end 6, and further has a thickness T larger than a thickness t of the other end 6. Thus, a portion of external lead 4 near the other end 6 converges in width and thickness toward the other end 6.

In QFN package 41 according to the second embodiment of the invention, external lead 4 is configured such that the thickness of the other end 6 is smaller than that of one end 5.

QFN package 41 having the above form can be produced by effecting half etching on the portion of the lead frame corresponding the other end 6 of external lead 4 from the side of main surface 3a of die pad 3 in the step corresponding to that of the first embodiment shown in FIG. 3.

According to QFN package 41 thus constructed, the resistance between external lead 4 and rotary blade 31 can be further reduced in the step corresponding to that of the first embodiment shown in FIG. 9. Thereby, it is possible to prevent more reliably the short circuit between neighboring external leads 4, and to reduce further the wearing of the rotary blade 31.

In the step corresponding to that of the first embodiment shown in FIG. 3, half etching may be effected on die bar 23 overlapping with cut line 22, whereby wearing of rotary blade 31 can be further reduced.

### Third Embodiment

A third embodiment differs from the first embodiment in the from of the lead frame used in the steps of manufacturing the QFN package. In the following. description, description of the same structures is not repeated.

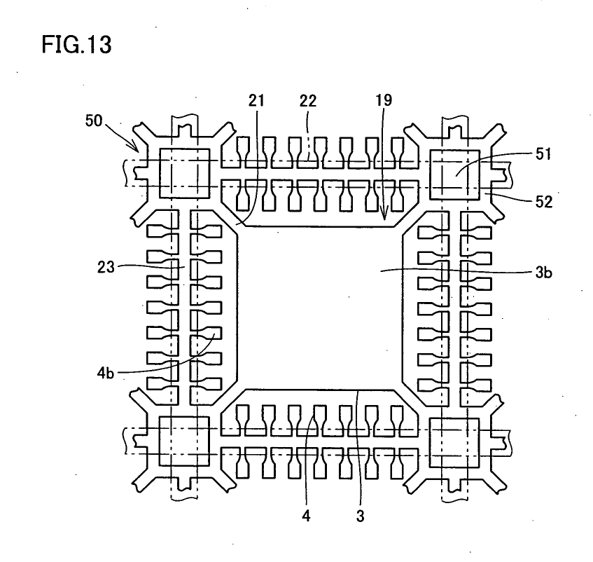

FIG. 13 corresponds to FIG. 4 showing the first embodiment.

Referring to FIG. 13, a lead frame 50 is used instead of lead frame 17 in the step corresponding to that of the first embodiment shown in FIG. 3. Lead frame 50 has basically the same structure as lead frame 17, but differs therefrom in that a rectangular frame portion 52 is formed on a crossing point defined by perpendicular die bars 23. Rectangular frame portion 52 defines an opening 51, which overlaps with cut line 22.

According to lead frame 50 having the above structure, rotating rotary blade 31, which is moved along cut line 22, does not cut the die bar 23 when it moves through an area of opening 51 in the step corresponding to that of the first embodiment shown in FIG. 9. Therefore, wearing of rotary blade 31 is further reduced.

### Fourth Embodiment

A QFN package according to a fourth embodiment of the invention has basically the same structure as QFN package 1 according to the first embodiment. In the following description, description of the same structures is not repeated.

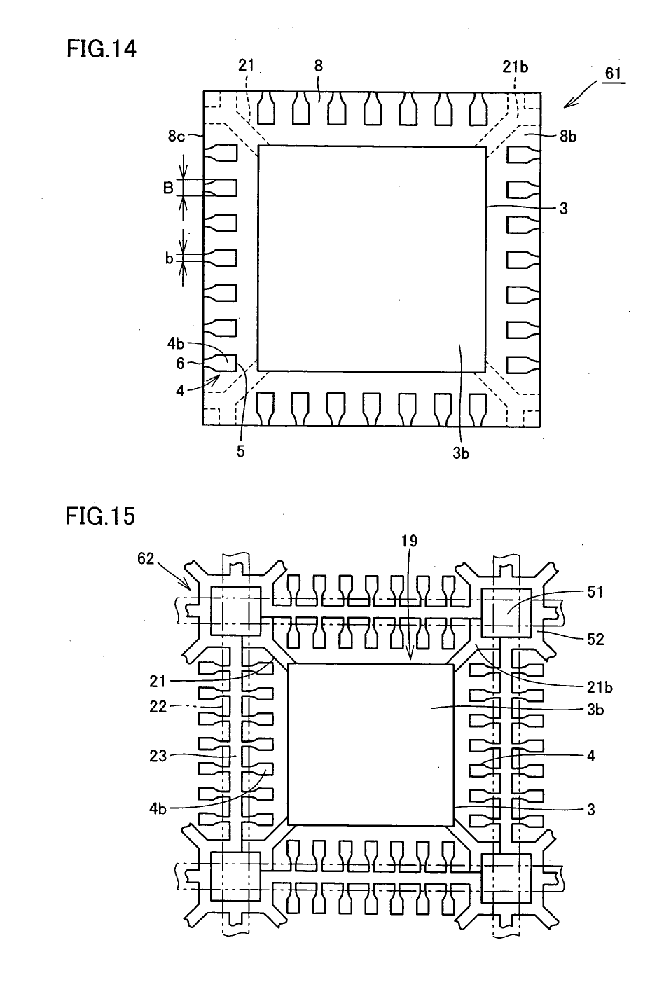

FIG. 14 corresponding to FIG. 2 showing the first embodiment.

Referring to FIG. 14, a QFN package 61 has four suspending leads 21 each extending from the corner of die pad 3 toward the periphery of the mold resin 8. Each suspending lead 21 has a front surface 21b, which extends parallel to rear surface 3b of die pad 3, and forms a stepped portion with respect to rear surface 3b. Surface 21b is covered with mold resin 8. Consequently, QFN package 61 has the same outer appearance as QFN package 1.

FIG. 15 corresponds to FIG. 4 showing the first embodiment.

According to the fourth embodiment, as shown in FIG. 15, half etching is effected on suspending leads 21 of lead frame 62 in the step corresponding to that of the first embodiment shown in FIG. 3. Thereby, surface 21b of suspending lead 21 is formed in a position shifted inward from rear surface 3b of die pad 3.

QFN package 61 according to the fourth embodiment of the invention further includes suspending leads 21 extending radiately from the periphery of die pad 3 and serving as suspending lead portions. Suspending lead 21 includes front surface 21b, which extends parallel-to rear surface 3b, and is covered with mold resin 8.

According to QFN package 61 having the above structure, mold resin 8 covers surface 21b of suspending lead 21. Therefore, even if QFN package 61 is positioned with respected to the interconnection board with an error in the step corresponding to that of the first embodiment shown in FIG. 11, short circuit between suspending lead 21 and the interconnection board can be prevented. For example, such a situation can be avoided that suspending lead 21 and external lead 4 neighboring to it are connected to the same terminal on the interconnection board. Thereby, QFN package 61 can be mounted on the interconnection board to allow intended operations.

### Fifth Embodiment

A QFN package according to a fifth embodiment of the invention has basically the same structure as QFN package 1 of the first embodiment. In the following description, description of the same structures is not repeated.

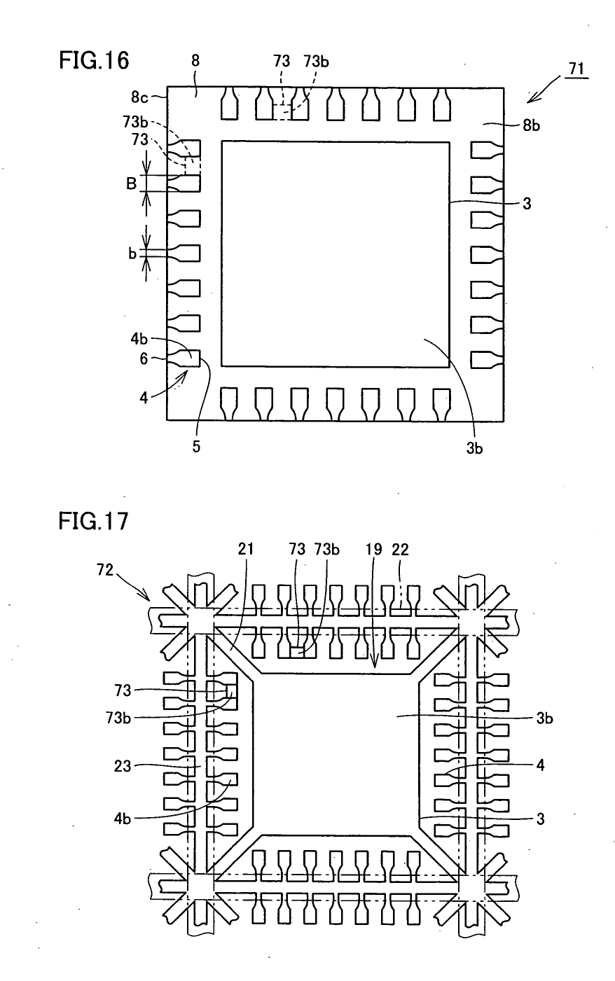

FIG. 16 corresponds to FIG. 2 showing the first embodiment.

Referring to FIG. 16, a QFN package 71 includes connection leads 73 each extending between neighboring external leads 4. Connection lead 73 has a surface 73b extending parallel to connection surface 4b of external lead 4, and forming a stepped portion with respect to connection surface 4b. Surface 73b is covered with mold resin 8. Consequently, QFN package 71 has the same appearance as QFN package 1. Connection lead 73 thus arranged can keep the same potential at external leads 4 connected thereby.

FIG. 17 corresponds to FIG. 4 showing the first embodiment.

Referring to FIG. 17, the structure of the fifth embodiment is prepared by effecting half etching on the portion of connection lead 73 of a lead frame 72 in the step corresponding to that of the first embodiment shown in FIG. 3. Thereby, surface 73b of connection lead 73 is formed in a position shifted inward from connection surface 4b of external lead 4.

QFN package 71 according to the fifth embodiment of the invention further includes connection leads 73 serving as the connection terminals each electrically connecting neighboring external leads 4 together. Connection lead 73 includes surface 73b, which extends parallel to connection surface 4b; and serves as a fourth surface covered with mold resin 8.

According to QFN package 71 having the above structure, neighboring external leads 4 can be electrically connected together without arranging the connection leads 73 in the exposed state and without performing connection processing with metal wires or the like. Thereby, even in a structure having an independent interconnection extending between the interconnection board terminals, to which neighboring external leads are connected, respectively, the neighboring leads 4 can be electrically connected together without employing a manner or structure such as an insulating coating film covering the above independent interconnection.

### Sixth Embodiment

A QFN package according to a sixth embodiment of the invention has basically the same structure as QFN package 1 of the first embodiment. In the following description, description of the same structures is not repeated.

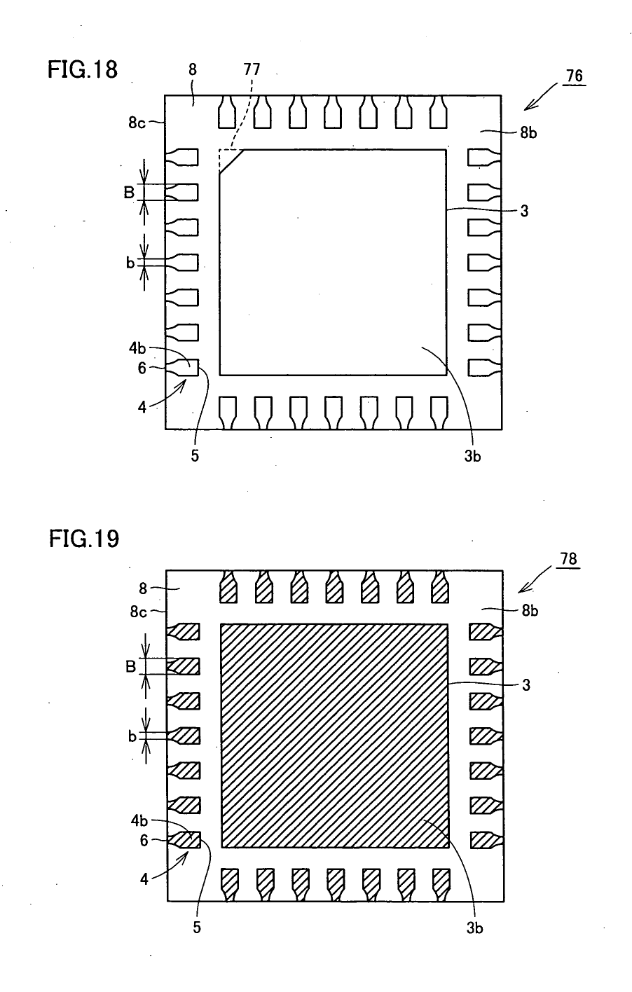

FIG. 18 corresponds to FIG. 2 showing the first embodiment. Referring to FIG. 18, a QFN package 76 is provided at one of corners of die pad 3 with a stepped portion 77. Stepped portion 77 has a surface lower than rear surface 3b of die pad 3. Stepped portion 77 is covered with mold resin 8.

QFN package 76 according to the sixth embodiment of the invention is provided at the corner of rear surface 3b of die pad 3 with stepped portion 77.

QFN package 76 can be prepared by effecting half etching on one of the corners of die pad 3 from the side of rear surface 3b in the step corresponding to that of the first embodiment shown in FIG. 3.

According to the QFN package 76 having the above structure, stepped portion 77 formed at the corner of die pad 3 can be used as an index when locating QFN package 76 in a predetermined position. For example, from the position of stepped portion 77, it is possible to determine the direction of QFN package 76 so that QFN package 76 can be located in the correct direction for mounting it on the interconnection board.

### Seventh Embodiment

A QFN package according to a seventh embodiment of the invention has basically the same structure as QFN package 1 of the first embodiment. In the following description, description of the same structures is not repeated.

FIG. 19 corresponds to FIG. 2 showing the first embodiment. Referring to FIG. 19, a QFN package 78 is provided at connection surfaces 4b of external leads 4 and rear surface 3b of die pad 3 with a large number of grooves, each of which has a narrow width and is spaced from the others. Instead of the grooves, connection surfaces 4b of external leads 4 and rear surface 3b of die pad 3 may have a satin-like finish.

In QFN package 78 according to the seventh embodiment of the invention, connection surfaces 4b and/or rear surface 3b have irregularities.

QFN package 78 can be prepared by effecting appropriate half etching on connection surfaces 4b and rear surface 3b in the step corresponding to that of the first embodiment shown in FIG. 3.

According to QFN package 78 having the above structure, the connection surfaces 4b and rear surface 3b can provide a large contact area with respect to solder when QFN package 78 is mounted on the interconnection board by soldering in the step corresponding to that of the first embodiment shown in FIG. 11. This can increase the adhesive properties of the solder with respect to connection surfaces 4b and rear surface 3b, and thus can improve the reliability in mounting of QFN package 78.

### Eighth Embodiment

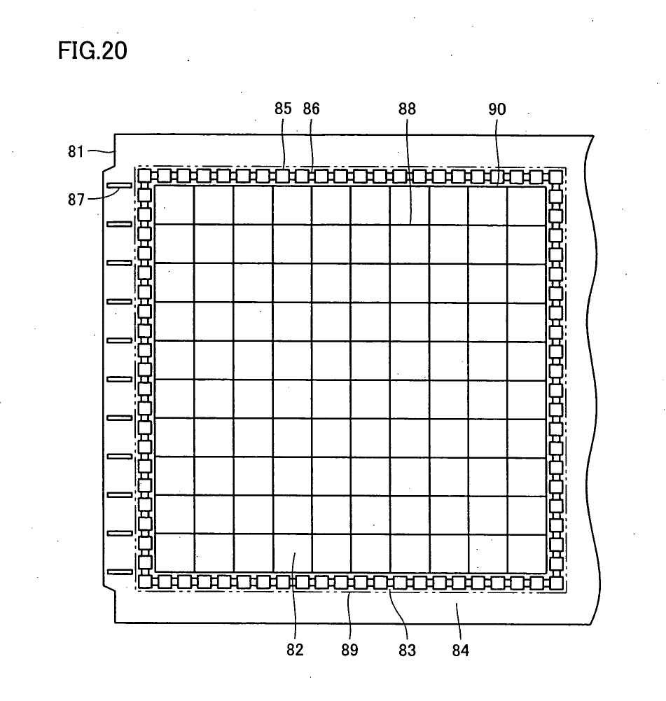

A lead frame shown in FIG. 20 is used instead of lead frame 17 in the step corresponding to that of the first embodiment shown in FIG. 3. By implementing the manufacturing method already described in connection with the first embodiment, the QFN packages in any one of the first to seven embodiment are produced from the lead frame shown in FIG. 20.

Referring to FIG. 20, a lead frame 81 is provided at its central portion with a semiconductor package formation region 90. Similarly to semiconductor package formation region 18 shown in FIG. 3, semiconductor package formation region 90 is provided with units 82 in a matrix form. These units 82 are formed of regions, which will be divided into independent semiconductor packages in a later step. A cut line 88 extends between neighboring units 82.

A mold end line 89 extends through a position spaced by a predetermined distance from a periphery of semiconductor package formation region 90. Mold end line 89 extends on the periphery of mold resin 28 (i.e., mold resin collectively covering the whole semiconductor package formation region 90) shown in FIGS. 7 and 8. Around semiconductor package formation region 90, there is formed a peripheral region 83 in a belt-like form, which is defined between the periphery of semiconductor package formation region 90 and mold end line 89. Peripheral region 83 is provided with openings 85, which are spaced by a predetermined distance from each other, and grooves 86 each extending between neighboring openings 85.

A peripheral region 84 extending along the periphery of lead frame 81 is defined around peripheral region 83. A plurality of slits 87 each extending on an extension of cut line 88 are formed in peripheral region 84.

Lead frame 81 according to the eighth embodiment is used for manufacturing the semiconductor packages according to any one of the first to seventh embodiments, and can be cut to provide the plurality of semiconductor packages. Lead frame 81 includes semiconductor package formation regions 90, each of which is formed of die pad 3 and the plurality of external leads 4 continuing to die pad 3. Semiconductor package formation regions 90 are formed of units 82 arranged in a matrix form, and provide the semiconductor device formation regions, respectively. Lead frame 81 further includes peripheral region 83, which extends in the belt-like form along the periphery of semiconductor package formation region 90, is provided with the plurality of openings 85 spaced from each other, and serves as the first peripheral region.

Peripheral region 83 is provided with grooves 86 extending between neighboring openings 85. Lead frame 81 further includes peripheral region 84, which extends in the belt-like form around the peripheral region 83, is provided with slits 87 extending in the same directions as the boundaries between neighboring units 82, and serves as the second peripheral region.

Lead frame 81 having the above structure is provided at peripheral region 83 with openings 85. Therefore, it is possible to improve the adhesive properties of mold resin 28 to peripheral region 83 of lead frame 81. Thereby, when rotary blade 31 cuts lead frame 81 in the step corresponding to that of the first embodiment shown in FIG. 9, it is possible to prevent peripheral region 83 of lead frame 81 from being spaced from mold resin 28. At the same time, mold resin 28 adhered to dicing sheet 30 keeps this adhered state. Consequently, such a situation can be avoided in the step of cutting lead frame 81 that cut pieces dispersed from lead frame 81 damage the semiconductor package.

It is preferable that opening 85 is formed in the position shifted from the extension of cut line 88. This can achieve the foregoing effect more reliably. Lead frame 81 is provided with grooves 86 formed between openings 85. This can further improve the adhesion properties of mold resin 28 with respect to peripheral region 83 of lead frame 81.

Lead frame 81 is provided with slits 87 each extending along the extension of cut line 88. As a result, rotary blade 31 moves along slits 87 when cutting peripheral region 84 of lead frame 81 in the step corresponding to that of the first embodiment shown in FIG. 9. This can reduce wearing of rotary blade 31.

According to the invention, as described above, short-circuit between the lead terminals can be reliably prevented, and it is possible to provide the semiconductor device and the lead frame allowing smooth cutting with the rotary blade.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device comprising:
a semiconductor chip;
a die pad including a main surface carrying said semiconductor chip;
a plurality of lead terminals arranged along a periphery of said die pad, spaced from each other and electrically connected to said semiconductor chip; and
a resin member covering said semiconductor chip, said die pad and partially said lead terminals, and including a side surface, wherein
each of said lead terminals has one end opposed to said semiconductor chip and the other end uncovered with said resin member and extending on the same plane as said side surface, and said other end is smaller in size in a direction of alignment of said plurality of lead terminals than said one end.

2. The semiconductor device according to claim 1, wherein
said other end has a thickness smaller than said one end.

3. The semiconductor device according to claim 1, wherein
said die pad further includes a first surface located on a side opposite to said main surface and uncovered with said resin member, and each of said lead terminals further includes a second surface located on the substantially same plane as said first surface, extending from said one end to said other end and uncovered with said resin member.

4. The semiconductor device according to claim 3, further comprising:
suspending lead portions extending radiately from a periphery of said die pad, wherein
each of said suspending lead portions includes a third surface extending parallel to said first surface, and covered with said resin member.

5. The semiconductor device according to claim 3, further comprising:
connection terminal each making an electrically connection between said lead terminals neighboring to each other, wherein
said connection terminal includes a fourth surface extending parallel to said second surface, and covered with said resin member.

6. The semiconductor device according to claim 3, wherein
at least one of said first and second surfaces has irregularities.

7. The semiconductor device according to claim 3, wherein
said die pad is provided on a corner of said first surface with a stepped portion.

8. A lead frame used for manufacturing the semiconductor device according to claim 1 by cutting said lead frame to produce the plurality of semiconductor devices, and comprising:
a semiconductor device formation region including units arranged in a matrix form, and each formed of said die pad and said plurality of lead terminals continuing to said die pad; and
a first peripheral region extending in a belt-like form along a periphery of said semiconductor device formation region, and provided with a plurality of openings spaced from each other.

9. The lead frame according to claim 8, wherein
said first peripheral region is provided with grooves extending between said openings neighboring to each other.

10. The lead frame according to claim 8, further comprising:
a second peripheral region extending in a belt-like form around said first peripheral region, and provided with slits extending in the same direction as boundaries between said units neighboring to each others.
